(19) United States
(12) Patent Application Publication
(10) Pub. No.: US 2016/0370422 A1
(43) Pub. Date: Dec. 22, 2016

(54) PROBING INTERPOSER AND SEMICONDUCTOR TEST SYSTEM INCLUDING THE SAME

(71) Applicant: Samsung Electronics Co., Ltd., Suwon-si (KR)

(72) Inventors: Taek-Sung Kim, Yongin-si (KR); Ji Eon Kim, Seoul (KR); SoonYong Hur, Hwaseong-si (KR)

(21) Appl. No.: 15/145,182

(22) Filed: May 3, 2016

(30) Foreign Application Priority Data
Jun. 18, 2015 (KR) 10-2015-0086755

(51) Int. Cl. G01R 31/28

(52) U.S. Cl. CPC G01R 31/2889

(57) ABSTRACT

A probing interposer includes a supporting substrate with first and second surfaces facing each other and via patterns penetrating the supporting substrate. Each of the via patterns have a concave portion that is exposed through the first surface and has a shape recessed in a direction from the first surface toward the second surface. The concave portion has a width that is smaller than that of the via pattern, and the width decreases in the direction from the first surface toward the second surface.

### CROSS-REFERENCE TO RELATED APPLICATIONS

This U.S. non-provisional patent application claims priority under 35 U.S.C. §119 to Korean Patent Application No. 10-2015-0086755, filed on Jun. 18, 2015, in the Korean Intellectual Property Office, the contents of which are herein incorporated by reference in their entirety.

### BACKGROUND OF THE INVENTION

Some example embodiments of the present inventive concepts relate to a semiconductor test system. Specifically, some of the example embodiments relate to a semiconductor test system, in which a probing interposer including a concave portion is provided.

In general, a semiconductor device is manufactured by a fabrication process including integrating circuit patterns on a wafer and an assembly process including assembling each semiconductor device obtained from the wafer. Between the fabrication process and the assembly process, an electrical die sorting (EDS) process is performed to test electric characteristics of each semiconductor device.

The EDS process is performed to determine if any of the semiconductor devices which constitute the wafer are defective. In the EDS process, a test system is used to apply electrical signals to the semiconductor devices constituting the wafer and to receive output signals from each semiconductor device. The output signals are used to determine whether the semiconductor device has failed, that is, is defective. A probe card with probe tips is provided in the test system. In the EDS process, the probe tips are disposed to be in physical contact with electrode pads of the semiconductor chip and, thus, can be used for electrical communication between the test system and the semiconductor devices.

### SUMMARY

Some example embodiments of the present inventive concepts provide a probing interposer configured to prevent bumps of a target device from being damaged.

Some example embodiments of the present inventive concepts provide a probing interposer, in which a via pattern comprising a concave portion is provided. The concave portion has a shape corresponding to a bump of a target device.

According to aspect of the present inventive concepts, a probing interposer may include a supporting substrate with first and second surfaces facing each other, and a plurality of via patterns penetrating the supporting substrate. Each of the plurality of via patterns may have a concave portion that is exposed through the first surface of the supporting substrate and has a shape recessed in a direction from the first surface of the supporting substrate toward the second surface of the supporting substrate, and the concave portion may have a width that is smaller than that of the corresponding via pattern, and the width decreases in the direction from the first surface of the supporting substrate toward the second surface of the supporting substrate.

In some embodiments, the probing interposer may further include a plurality of electrode pads that are provided on the second surface of the supporting substrate and are electrically connected to the plurality of via patterns, respectively.

In some embodiments, the probing interposer may further include a re-distribution layer that is provided on the second surface of the supporting substrate and is electrically connected to the via patterns.

In some embodiments, the probing interposer may further include a plurality of electrode pads provided on the re-distribution layer. The plurality of electrode pads may be electrically connected to the plurality of via patterns through the re-distribution layer.

In some embodiments, a first space between the plurality of electrode pads may be larger than a second space between the plurality of via patterns.

In some embodiments, each of the plurality of electrode pads may have a width larger than the second space between the plurality of via patterns.

In some embodiments, the plurality of via patterns may be spaced apart from each other by a uniform distance, and the first surface of the supporting substrate may have an uneven surface, on which the concave portions may be successively arranged.

In some embodiments, the concave portion may have a surface shaped like a curved bowl.

In some embodiments, the plurality of via patterns may include at least one of tungsten (W), lead (Pd), cobalt (Co), nickel (Ni), gold (Au), rhenium (Re), rhodium (Rh), or alloys thereof.

In some embodiments, the probing interposer may further include an insulating layer provided between the via patterns and the supporting substrate.

According to another aspect of the present inventive concepts, a test system may include a chuck configured to load a target device with a plurality of bumps, a probing interposer configured to be in contact with the plurality of bumps of the target device, and a probe card provided on the probing interposer, the probe card including probe tips configured to be in contact with the probing interposer and to apply test signals to the target device. The probing interposer may include a supporting substrate with first and second surfaces facing each other, and a plurality of via patterns provided to penetrate the supporting substrate. Each of the plurality of via patterns may have a concave portion that is recessed in a direction from the first surface of the supporting substrate toward the second surface of the supporting substrate, and the concave portions may be used for contact between the plurality of via patterns and the plurality of bumps. The concave portion may have a diameter smaller than that of the corresponding via pattern and may be tapered in the direction from the first surface of the supporting substrate toward the second surface of the supporting substrate.

In some embodiments, the probing interposer of the test system may further include a plurality of electrode pads that are provided on the second surface of the supporting substrate and are in contact with the probe tips.

In some embodiments, the probing interposer of the test system may further include a re-distribution layer provided on the second surface of the supporting substrate. The re-distribution layer may include a plurality of metal layers electrically connected to the plurality of via patterns and an insulating layer provided between the metal layers.

In some embodiments, the probing interposer of the test system may further include a plurality of electrode pads that are provided on the re-distribution layer and are in contact with the probe tips. A first space between the plurality of electrode pads may be greater than a second space between the plurality of via patterns.

In some embodiments, the concave portion may have a recess depth smaller than a height of the bump protruding from the target device, when measured in the direction from the first surface toward the second surface.

According to another aspect of the present inventive concepts, a method of manufacturing a probing interposer may include providing a supporting substrate with first and second surface facing each other, forming a plurality of via holes in the supporting substrate, filling the plurality of via holes with a conductive material to form a plurality of via patterns, forming concave portions in the plurality of via patterns, respectively, to have a profile recessed in a direction from the first surface of the supporting substrate toward the second surface of the supporting substrate, and forming a plurality of electrode pads on the second surface of the supporting substrate to be electrically connected to the plurality of via patterns. The concave portion may be formed to have a shape tapered in the direction from the first surface of the supporting substrate toward the second surface of the supporting substrate.

In some embodiments, the method may further include performing a polishing process to expose the plurality of via patterns through the second surface of the supporting substrate.

In some embodiments, the electrode pads may be formed to be in contact with the plurality of via patterns exposed by the first surface of the supporting substrate.

In some embodiments, the method may further include forming a re-distribution layer on the plurality of via patterns exposed by the polishing process. The electrode pads may be electrically connected to the re-distribution layer.

In some embodiments, the forming of the concave portion may include forming a mask on the first surface of the supporting substrate to expose the plurality of via patterns, performing a wet etching process on the exposed plurality of via patterns to form a recess region, and performing a plasma treatment on the recess region to reduce surface roughness of the recess region.

According to another aspect of the present inventive concepts, a probing interposer includes a supporting substrate having a first surface and a second surface opposite the first surface, a plurality of via patterns extending through the supporting substrate from the first surface of the supporting substrate to the second surface of the supporting substrate in a vertical direction of extension relative to a horizontal direction of extension of the supporting substrate, and a concave portion in each of the plurality of via patterns along the first surface of the support substrate. The concave portion may be a recess extending from the first surface of the supporting substrate to the second surface of the supporting substrate.

In some embodiments, the probing interposer may further include an insulating layer provided between the via patterns and the supporting substrate extending through the supporting substrate from the first surface of the supporting substrate to the second surface of the supporting substrate in a vertical direction of extension relative to a horizontal direction of extension of the supporting substrate.

In some embodiments, the probing interposer may further include a plurality of electrode pads that are provided on the second surface of the supporting substrate and are electrically connected to the plurality of via patterns, respectively.

In some embodiments, the plurality of electrode pads cover an exposed surface of the plurality of via patterns, respectively.

In some embodiments, the concave portion has a width that is smaller than that of the corresponding via pattern, and the width decreases in the direction from the first surface of the supporting substrate toward the second surface of the supporting substrate

### BRIEF DESCRIPTION OF THE DRAWINGS

The foregoing and other features and advantages of the inventive concepts will be apparent from the more particular description of preferred embodiments of the inventive concepts, as illustrated in the accompanying drawings in which like reference characters refer to the same parts throughout the different views. The drawings are not necessarily to scale, emphasis instead being placed upon illustrating the principles of the inventive concepts.

FIG. 1 is a schematic diagram illustrating a semiconductor test system according to some example embodiments of the present inventive concepts.

FIG. 2 is an enlarged cross-sectional view illustrating a portion “A” of FIG. 1.

FIG. 3 is an enlarged cross-sectional view illustrating a probing interposer according to some example embodiments of the present inventive concepts.

FIG. 4 is an enlarged cross-sectional view illustrating a portion “D” of FIG. 3.

FIGS. 5A through 5I are cross-sectional views illustrating a method of manufacturing the probing interposer of FIG. 3 according to some example embodiments of the present inventive concepts.

FIG. 6 is an enlarged cross-sectional view illustrating a probing interposer according to some example embodiments of the present inventive concepts.

FIGS. 7A and 7B are cross-sectional views illustrating a method of manufacturing the probing interposer of FIG. 6 according to some example embodiments of the present inventive concepts.

### DETAILED DESCRIPTION

Various example embodiments of the inventive concepts will now be described more fully with reference to the accompanying drawings, in which example embodiments are shown. Example embodiments of the present inventive concepts may, however, be embodied in many different forms and should not be construed as being limited to the example embodiments set forth herein.

It will be understood that when an element is referred to as being “on,” “connected to” or “coupled to” another element or layer, it can be directly on, connected or coupled to the other element or layer or intervening elements or layers may be present. In contrast, when an element or layer is referred to as being “directly on,” “directly connected to” or “directly coupled to” another element or layer, there are no intervening elements or layers present. Like numerals refer to like elements throughout. As used herein the term “and/or” includes any and all combinations of one or more of the associated listed items.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present inventive concepts.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concepts. As used herein, the singular forms “a,” “an” and “the” are intended to include the plural forms as well, unless the context clearly indicates otherwise. It will be further understood that the teams “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure (e.g., a memory cell structure or a transistor structure) is illustrated in a cross-sectional view, an electronic device may include a plurality of the device structures (e.g., memory cell structures or transistor structures), as would be illustrated by a plan view of the electronic device. The plurality of device structures may be arranged in an array and/or in a two-dimensional pattern.

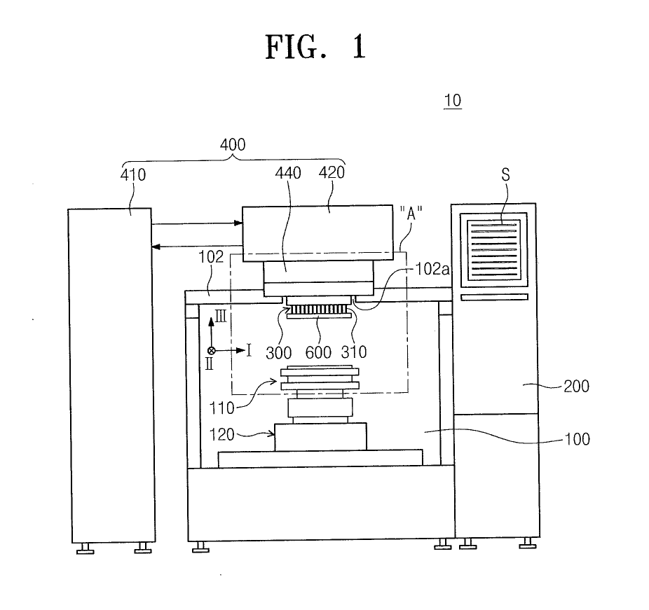

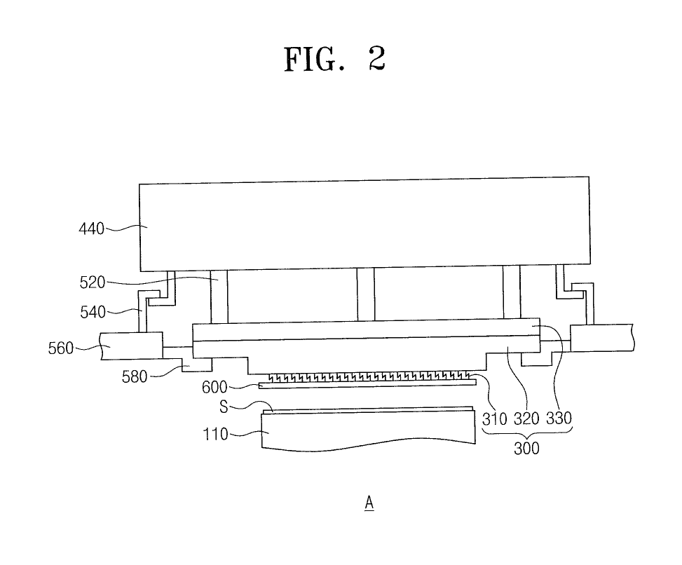

FIG. 1 is a schematic diagram illustrating a semiconductor test system 10 according to some example embodiments of the present inventive concepts, and FIG. 2 is an enlarged cross-sectional view illustrating a portion “A” of FIG. 1.

Referring to FIGS. 1 and 2, the semiconductor test system 10 may include a prober room 100, a loader room 200, a probe card 300, a tester 400, and a probing interposer 600.

In some embodiments, the prober room 100 may provide a space for an electrical die sorting (EDS) process including testing electric characteristics of semiconductor devices. The loader room 200 may be disposed adjacent to the prober room 100. In some embodiments, the loader room 200 may be disposed adjacent to the prober room 100 in a substantially horizontal direction, for example, horizontal direction I. The loader room 200 may be configured to store a target device S, and transfer the target device S to the prober room 100. The EDS process will be performed on the target device S. A chuck 110 may be disposed in the prober room 100, and the probe card 300 may be provided in a hole 102a and may extend through hole 102a to face the chuck 110. The hole 102a may be formed in a top cover 102 of the prober room 100. The target device S may be transferred from the loader room 200 and may be loaded on the chuck 110.

The chuck 110 may be disposed on a transfer unit 120. The target device S may be fastened to the chuck 110 using a vacuum, suction pressure applied between the target device S and the chuck 110. Sandpaper (not shown) may be disposed near or on the chuck 110. The sandpaper (not shown) may have a rough surface. Accordingly, in an embodiment in which probe tips 310 of the probe card 300 have contaminants thereon, the probe tips 310 may be rubbed on the rough surface of the sandpaper (not shown) in order to remove the contaminants from the probe tips 310. The target device S may be loaded on the chuck 110 from the loader room 200.

The transfer unit 120 may be configured to move the chuck 110 in a horizontal direction I and/or II and in a vertical direction III, and moreover, to rotate the chuck 110 about an axis normal to a surface of the target device S. The horizontal directions I and/or II may be substantially parallel to a top surface of the target device S, on which semiconductor devices are integrated, and the vertical direction III may be substantially perpendicular to the top surface of the target device S.

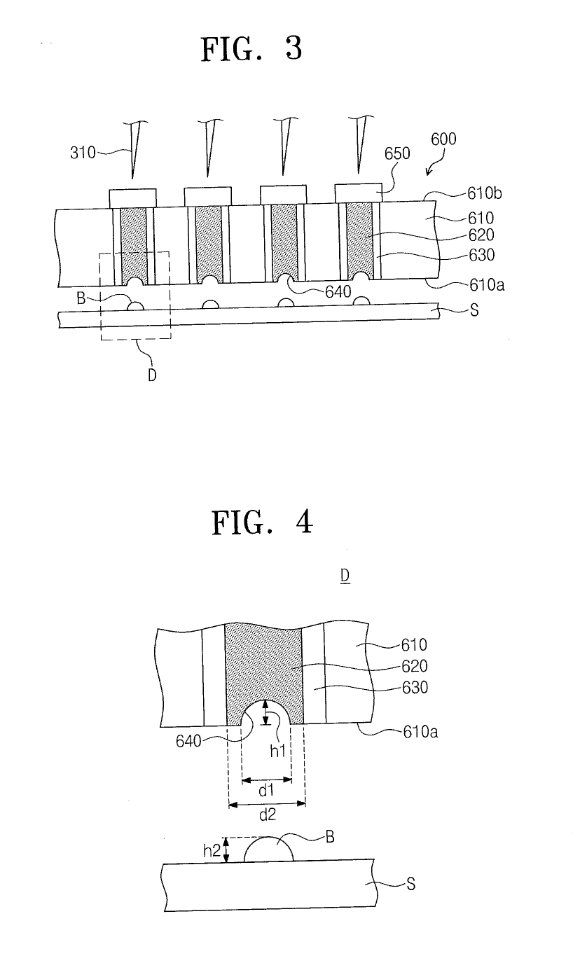

By rotating the chuck 110 using the transfer unit 120, it is possible to adjust an orientation of the target device S relative to the probe card 300. For example, bumps B of the target device S may be positioned parallel to the probe tips 310 of the probe card 300, as illustrated in FIG. 3. By moving the chuck 110 in the horizontal direction I and/or II using the transfer unit 120, the bumps B or electrode terminals of the target device S may be positioned under the probe tips 310 of the probe card 300 in a vertical direction. The probing interposer 600 may be disposed between the probe tips 310 and the target device S. The probing interposer 600 may prevent the target device S from being damaged. By moving the chuck 110 in the vertical direction using the transfer unit 120, the bumps B of the target device S may be in physical contact with the probing interposer 600 (see FIG. 3). That is, the transfer unit 120 may adjust the position of the chuck 110 in the horizontal direction I and/or II and/or the vertical direction III such that the bumps B of the target device S are in physical contact with the probing interposer 600. In some embodiments the bumps B may be in direct physical contact with the probing interposer 600.

The probe card 300 may be provided over the chuck 110. The probe card 300 may include the probe tips 310, a probe substrate 320, and a stiffener 330. The probe substrate 320 may be shaped, for example, like a circular disk. The probe substrate 320 may be formed of, for example, a glass epoxy resin. The stiffener 330 may be provided on the probe substrate 320. For example, the stiffener 330 may be provided on a top surface of the probe substrate 320. The stiffener 330 may be provided to prevent the probe substrate 320 from being deformed, for example, curved or distorted. The probe tips 310 may be provided on a bottom surface of the probe substrate 320 to be in physical contact with the probing interposer 600. That is, the probe tips 310 may be provided on a surface of the probe substrate 320 opposite to the surface of the probe substrate 320 on which the stiffener 330 is formed. Each of the probe tips 310 may be provided, for example, in the form of a needle with a small width. Each of the probe tips 310 may be used as a path for transmitting test signals between the tester 400 and the target device S. The number of the probe tips 310 may be determined, depending on the number of electrode pads, for example, electrode pads 650 of FIG. 3, of the probing interposer 600.

The tester 400 may include a tester body 410 and a tester head 420. The tester body 410 may be disposed adjacent to the prober room 100, in, for example, a substantially horizontal direction. The tester body 410 may be configured to send input signals to a semiconductor device, for example, on the target device S, and to receive output signals from the semiconductor device, and the output signals may be used to determine whether the semiconductor device tested is defective. The tester head 420 may be electrically connected to the tester body 410. The tester body 410 may include a base unit 440 to which the probe card 300 is coupled. The tester head 420 may be configured to allow for electric signals to be transmitted between the probe card 300 coupled to the base unit 440 and the tester body 410. The tester head 420 and the base unit 440 may be disposed over the prober room 100 in a substantially vertical direction.

The tester body 410 may generate the input signals for testing electric characteristics of a semiconductor device. The tester head 420 may be configured to transmit the input signals from the tester body 410 to the probe card 300. The input signals transmitted to the probe card 300 may be applied to the target device S through the probe tips 310 and the probing interposer 600. Referring to FIGS. 1 through 3, the input signals from the probe card 300 may be used to perform a specific operation on the target device S, and the output signals generated from the operation may be transmitted from the target device S to the tester body 410 through the bumps B. The output signals output from the bumps B of the target device S may be transmitted to the probe card 300 through the probing interposer 600 and the probe tips 310. Referring back to FIGS. 1 and 2, the probe card 300 may transmit the output signals from the target device S to the tester head 420. The tester body 410 may determine whether the target device S is operating normally or abnormally based on the output signals transmitted from the tester head 420.

As illustrated in FIG. 2, in some embodiments, at least one cylinder 520 may be disposed between the base unit 440 and the probe card 300. In some embodiments, a plurality of cylinders 520 may be provided between the base unit 440 and the probe card 300 on center and/or edge regions of the probe card 300. The cylinder 520 may serve as an elastic component. For example, the cylinder 520 may be provided in the form of a coil spring or elastic rubber. The cylinder 520 may be disposed to connect the base unit 440 to the probe card 300 and thus may serve as a buffer, reducing pressure applied to the probe card 300, when the target device S is tested.

A supporting unit 540 may include one end connected to a bottom surface of the base unit 440. An opposite end of the supporting unit 540 may be connected to a head plate 560. The head plate 560 may be fixedly attached to the prober room 100. A fastening unit 580 may be connected to the head plate 560. The probe card 300 may be disposed on the fastening unit 580. The fastening unit 580 may be disposed to be in at least partial contact with bottom and side surfaces of the probe card 300, thus, the probe card 300 may be fastened to the prober room 100. The fastening unit 580 may be provided to have a stepwise, ring-shaped structure with an opening. The probe substrate 320 and the probe tips 310 may be exposed through the opening of the fastening unit 580. The probe substrate 320 is partially exposed through the opening.

The probing interposer 600 may be provided between the target device S and the probe card 300. The probing interposer 600 may be in contact with the probe tips 310 of the probe card 300. For example, the probing interposer 600 may be in direct contact with the probe tips 310. The probing interposer 600 may prevent the target device S from being in direct contact with the probe tips 310, thus, preventing the target device S from being damaged by the probe tips 310. Furthermore, the probing interposer 600 may be configured to electrically connect the probe tips 310 to the target device S.

FIG. 3 is an enlarged cross-sectional view illustrating the probing interposer 600 according to some example embodiments of the present inventive concepts, and FIG. 4 is an enlarged cross-sectional view illustrating a portion “D” of FIG. 3.

Referring to FIGS. 3 and 4, the probing interposer 600 may include a supporting substrate 610, at least one via pattern 620, an insulating layer 630, a concave portion 640, and at least one electrode pad 650.

The supporting substrate 610 may be disposed between the target device S and the probe tips 310. The supporting substrate 610 may have a first surface 610a facing the bump B of the target device S and a second surface 610b opposite to the first surface 610a. The supporting substrate 610 may have a shape, for example, a circular disk shape, corresponding or similar to that of the probe substrate 320. The supporting substrate 610 may be, for example, formed of, or include, at least one of silicon (Si), gallium arsenic (GaAs), or compounds thereof.

The at least one via pattern 620 may be provided to penetrate the supporting substrate 610. The at least one via pattern 620 may be exposed through the first surface 610a of the supporting substrate 610 and may extend from the first surface 610a of the supporting substrate 610 to the second surface 610b. A plurality of the via patterns 620 may be provided in the supporting substrate 610, and the via patterns 620 may be disposed spaced apart from each other by, for example, a uniform space. The plurality of via patterns 620 extend in a vertical direction of extension relative to a horizontal direction of extension of the supporting substrate 610. The via patterns 620 may be positioned to be in contact with and electrically connected to the bumps B of the target device S. The via patterns 620 may be formed of a conductive and soft metallic material, for example, tungsten (W), lead (Pd), cobalt (Co), nickel (Ni), gold (Au), rhenium (Re), rhodium (Rh), and/or alloys thereof.

The insulating layer 630 may be provided between the plurality of via patterns 620 and the supporting substrate 610, thus, preventing short circuits from being generated between the plurality of via patterns 620. The insulating layer 630 may be provided on outer side surfaces of the via patterns 620 and may extend from the first surface 610a to the second surface 610b, similar to the via patterns 620. The insulating layers 630 extend between the plurality of via patterns and the supporting substrate 610 from the first surface 610a of the supporting substrate 610 to the second surface 610b of the supporting substrate 610 in a vertical direction of extension relative to a horizontal direction of extension of the supporting substrate 610. The insulating layer 630 may be, for example, formed of, or include, a resin.

Each of the plurality of via patterns 620 may have the concave portion 640 along the first surface 610a of the supporting substrate 610. The concave portion 640 may have a recessed shape in a direction from the first surface 610a toward the second surface 610b. That is, the concave portion 640 may be a recess formed in the via pattern 620 in a direction from the first surface 610a toward the second surface 610b. Since the concave portions 640 are successively arranged on the first surface 610a in the via pattern 620, the first surface 610a may have an uneven surface profile. As illustrated in FIG. 4, on the first surface 610a of the supporting substrate 610, the concave portion 640 may have a width d1 smaller than a width d2 of the via pattern 620 and the width of the concave portion 640 may decreased in a direction from the first surface 610a toward the second surface 610b. When measured in the direction from the first surface 610a toward the second surface 610b, a depth h1 of the concave portion 640 may be smaller than a height h2 of the bump B protruding from the target device S. In the embodiment in which the protruding height h2 of the bump B is greater than the depth h1 of the concave portion 640, the concave portion 640 may easily contact the bump B and a contact area between the concave portion 640 and the bump B may increase. The increase in contact area between the concave portion 640 and the bump B may lead to a reduction in contact resistance between the probing interposer 600 and the target device S. Furthermore, the concave portion 640 may have a shape corresponding or similar to that of the bump B, thereby protecting the bump B of the target device S. In the embodiment in which the concave portion 640 is provided to have a shape corresponding or similar to that of the bump B, the bump B may be protected from being damaged, when the EDS process is performed on the target device S. For example, the concave portion 640 may be shaped like a bowl.

The at least one electrode pad 650 may be provided to be in contact with the via pattern 620 exposed by the second surface 610b of the supporting substrate 610. In some embodiments, a plurality of the electrode pads 650 may be provided on the second surface 610b of the supporting substrate 610 to be in contact with the plurality of via patterns 620 and may be disposed spaced apart from each other by, for example, a uniform distance. The number of the electrode pads 650 may be the same as that of the probe tips 310 and/or the via patterns 620; however, example embodiments of the present inventive concepts are not limited thereto. During the EDS process, the electrode pads 650 may be in physical contact with the probe tips 310 and may allow for exchange of test signals between the probe tips 310 and the target device S. That is, the electrode pads 650 may be in direct physical contact with the probe tips 310 during the EDS process. The at least one electrode pad 650 may include, for example, at least one of titanium (Ti), nickel (Ni), gold (Au), or copper (Cu).

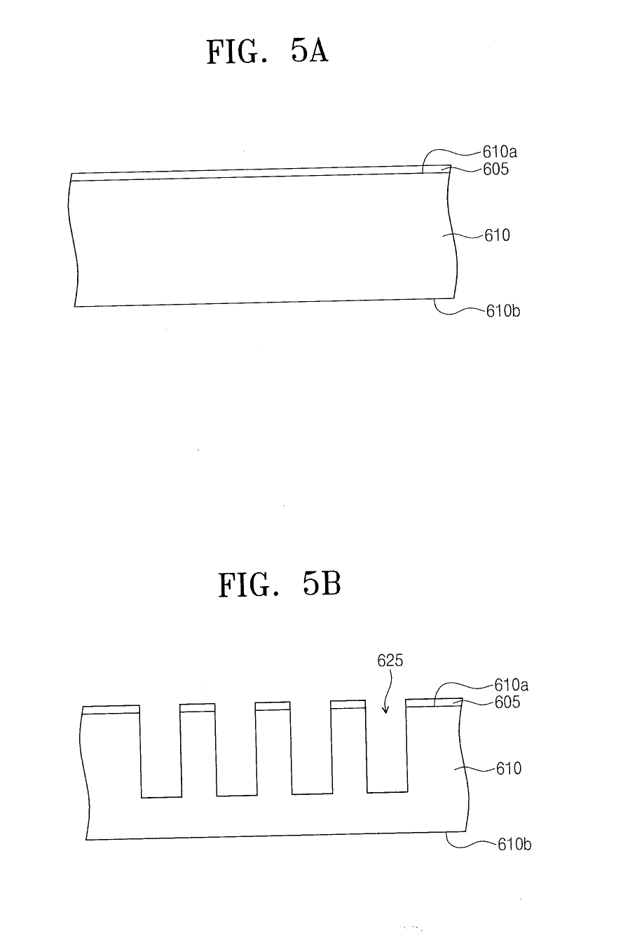

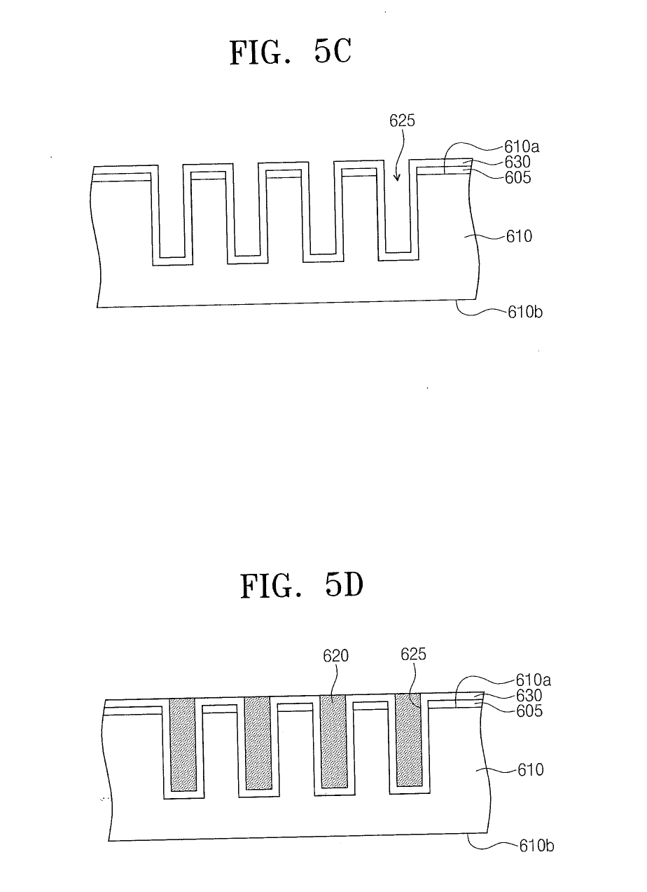

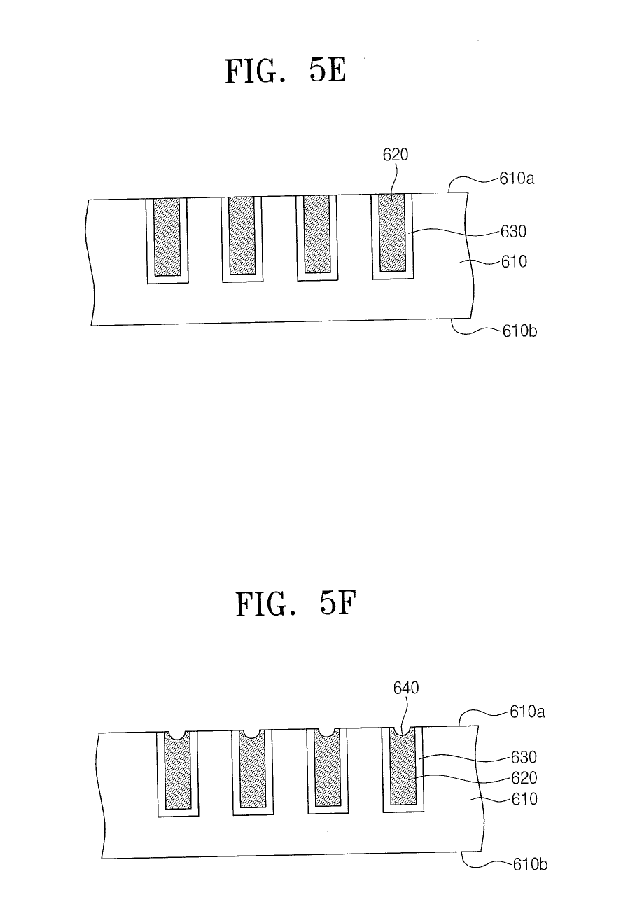

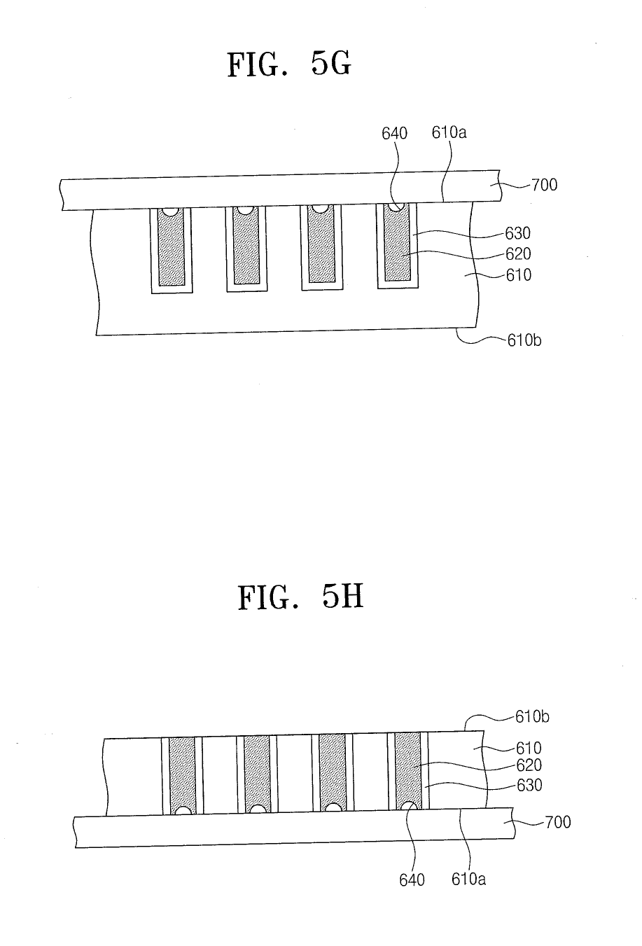

FIGS. 5A through 5I are cross-sectional views illustrating a method of manufacturing the probing interposer 600 of FIG. 3 according to some example embodiments of the present inventive concepts.

Referring to FIG. 5A, a silicon oxide layer 605 may be formed on the first surface 610a of the supporting substrate 610. The silicon oxide layer 605 may be provided to form a photoresist layer (not shown) in a lithography process.

Referring to FIG. 5B, a plurality of via holes 625 may be formed in the supporting substrate 610. The formation of the via holes 625 may include forming a photoresist layer (not shown) on the silicon oxide layer 605 and performing an etching process on the supporting substrate 610, using the photoresist layer (not shown) as an etch mask. In some example embodiments, the via holes 625 may be formed by a laser drilling process. The via holes 625 may be formed to extend from the first surface 610a of the supporting substrate 610 toward the second surface 610b. The via holes 625 extend in a substantially vertical direction of extension relative to a horizontal direction of extension of the supporting substrate 610.

Referring to FIG. 5C, the insulating layer 630 may be formed to conformally cover the silicon oxide layer 605 and the via holes 625. The insulating layer 630 may be, for example, a resin layer.

Referring to FIG. 5D, the at least one via pattern 620 may be formed by filling the via hole 625 with, for example, a conductive material. The via pattern 620 may be formed to extend from the first surface 610a of the supporting substrate 610 toward the second surface 610b. The via pattern 620 may be, for example, formed of, or include, at least one of tungsten (W), lead (Pd), cobalt (Co), nickel (Ni), gold (Au), rhenium (Re), rhodium (Rh), and/or alloys thereof.

Referring to FIG. 5E, a polishing process may be performed on the supporting substrate 610. The polishing process may be performed using, for example, a chemical mechanical polishing (CMP) process or a dry etching process. For example, the polishing process may be performed to polish the silicon oxide layer 605 and the insulating layer 630, thereby exposing the first surface 610a of the supporting substrate 610 thereunder. That is, the supporting substrate 610 along the first surface 610a between the via holes 625 may be exposed. In some embodiments, the polishing process may be performed to remove the silicon oxide layer 605 and the insulating layer 630 provided on the silicon oxide layer 605 to expose the first surface 610a.

Referring to FIGS. 3 and 5F, the concave portion 640 may be formed on the at lease one via pattern 620. The concave portion 640 may be formed by, for example, a wet etching process. By controlling a process time and an etch rate of the wet etching process, it may be possible to adjust a size and a shape of the concave portion 640. In some embodiments, an anisotropic wet etching process may be performed to realize the bowl-shaped structure of the concave portion 640. In some embodiments, the concave portion 640 may be tapered in such a way that its width decreases in a direction from the first surface 610a toward the second surface 610b. After the wet etching process, the surface of the concave portion 640 may be treated by, for example, plasma. The plasma treatment may result in the concave portion 640 to having a smooth surface. In the embodiment in which the concave portion 640 has an increased surface smoothness, a contact property between the concave portion 640 and the target device S may be improved.

Referring to FIG. 5G, a carrier film 700 may be attached to the first surface 610a of the supporting substrate 610. The carrier film 700 may support the supporting substrate 610, when the supporting substrate 610 is inverted in a subsequent step.

Referring to FIG. 5H, the supporting substrate 610 may be inverted, and, for example, a polishing process may be performed on the second surface 610b of the supporting substrate 610. The polishing process may be performed using, for example, a chemical mechanical polishing (CMP) process or a dry etching process. As a result of the polishing process, the at least one via pattern 620 and the insulating layer 630 may be exposed and the second surface 610b of the supporting substrate 610 may be connected to the first surface 610a of the supporting substrate 610 through the via pattern 620.

Referring to FIG. 5I, the at least one electrode pad 650 may be formed on the second surface 610b of the supporting substrate 610. The at least one electrode pad 650 may cover the exposed at least one via pattern 620, the insulating layer 630, and a portion of the supporting substrate 610 along the second surface 610b. The at least one electrode pad 650 may be provided to be in contact with the at least one via pattern 620 and the insulating layer 630. In some embodiments, a plurality of electrode pads 650 may be provided to be spaced apart from each other by, for example, a uniform distance and may be formed on the plurality of via patterns 620. The at least one electrode pad 650 may be formed of, for example, a conductive material and may be electrically connected to the at least one via pattern 620.

According to the aforementioned method of manufacturing the probing interposer 600, a surface of the concave portion 640 may be treated by plasma resulting in the omission of a process of forming an additional metal layer thereon. In addition, by forming the concave portion 640 in the at least one via pattern 620, the concave portion 640 may be electrically connected to the bump B of the target device S and a process of manufacturing the probing interposer 600 may be simplified.

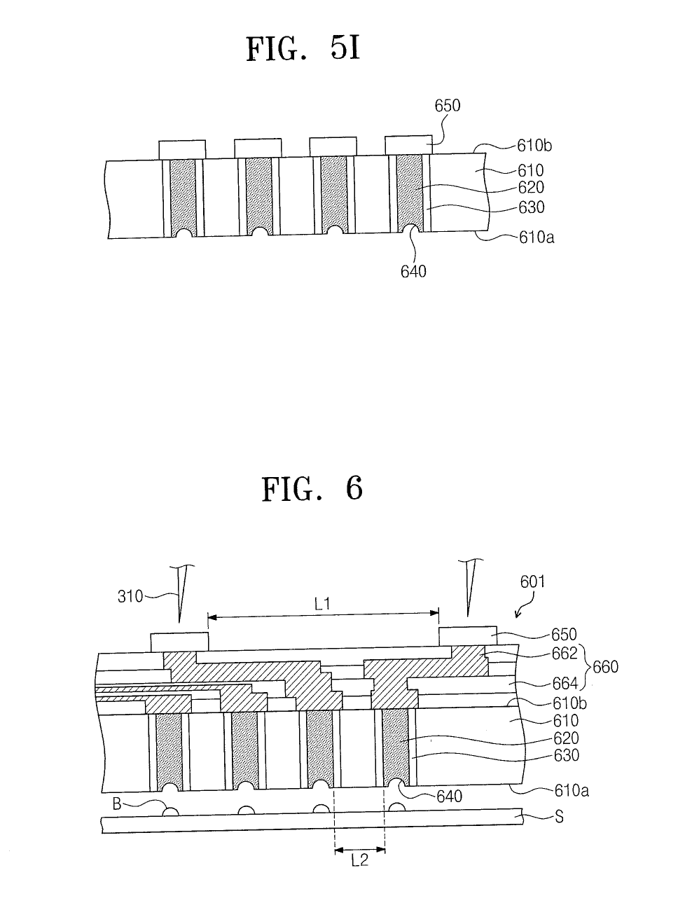

FIG. 6 is an enlarged cross-sectional view illustrating a probing interposer 601 according to some example embodiments of the present inventive concepts. For concise description, a previously described element may be identified by a similar or identical reference number without repeating an overlapping description thereof.

Referring to FIG. 6, the probing interposer 601 may include the supporting substrate 610, the at least one via pattern 620, the insulating layer 630, the concave portion 640, the at least one electrode pad 650, and a re-distribution layer 660.

The supporting substrate 610 may be disposed on the target device S. The supporting substrate 610 may be, for example, formed of, or include, at least one of silicon (Si), gallium arsenic (GaAs), and/or compounds thereof. In some embodiments, a plurality of the via patterns 620 may be provided in the supporting substrate 610, and the first surface 610a of the supporting substrate 610 may be connected to the second surface 610b through the via patterns 620. The plurality of via patterns 620 extend in a vertical direction of extension relative to a horizontal direction of extension of the supporting substrate 610. The plurality of via patterns 620 may be formed of, for example, a conductive and soft metallic material, and the plurality of via patterns 620 may be positioned to be in contact with the bumps B of the target device S. For example, the via pattern 620 may be formed of, or include, at least one of tungsten (W), lead (Pd), cobalt (Co), nickel (Ni), gold (Au), rhenium (Re), rhodium (Rh), and/or alloys thereof.

The insulating layer 630 may be provided between the plurality of via patterns 620 and the supporting substrate 610, thereby, preventing an electric short circuit from being generated between the plurality of via patterns 620. The insulating layers 630 extend between the plurality of via patterns and the supporting substrate 610 from the first surface 610a of the supporting substrate 610 to the second surface 610b of the supporting substrate 610 in a vertical direction of extension relative to a horizontal direction of extension of the supporting substrate 610. The insulating layer 630 may be, for example, formed of, or include, a resin.

The concave portions 640 may be formed on an exposed surface of each of the plurality of via patterns 620 and along to the first surface 610a of the supporting substrate 610. The concave portion 640 may be provided to have substantially the same features as that described with reference to FIGS. 3 and 4, and, thus, a detailed description thereof will be omitted.

The re-distribution layer 660 may be provided on the second surface 610b of the supporting substrate 610. The re-distribution layer 660 may include a plurality of metal layers 662, which are electrically connected to the plurality of via patterns 620, and an insulating layer 664, or a plurality of insulating layers, which is provided between the metal layers 662. The metal layers 662 may cover the exposed at least one via pattern 620, the exposed insulating layer 630 and a portion of the exposed supporting substrate 610 along the second surface 610b.

The at least one electrode pad 650 may be provided on the re-distribution layer 660. The at least one electrode pad 650 may cover the metal layer 662 and a portion of the insulating layer 644. A plurality of the electrode pads 650 may be in contact with the plurality of metal layers 662. The at least one via pattern 620, the metal layers 662, and the at least one electrode pad 650 may be electrically connected to each other. The at least one electrode pad 650 may include, for example, at least one of titanium (Ti), nickel (Ni), gold (Au), and/or copper (Cu). The arrangement of the metal layers 662 may be controlled to adjust a space between the plurality of electrode pads 650. A space between the plurality of electrode pads 650 (hereinafter, a first space L1) may be larger than a space between the plurality of via patterns 620 (hereinafter, a second space L2). If the first space L1 increases, an area of the electrode pad 650 may be increased. In some embodiments, the plurality of electrode pads 650 may be disposed to have a width larger than the second space L2 between the via patterns 620, resulting in the probe tips 310 being in stable contact with the electrode pads 650. Thus, when a test operation is performed on the target device S, the probe tips 310 and the electrode pads 650 may be prevented from being disconnected and the probe tips 310 may be more easily connected to the electrode pads 650. That is, the degree of freedom in a contact step between the probe tips 310 and the electrode pads 650 may be increased.

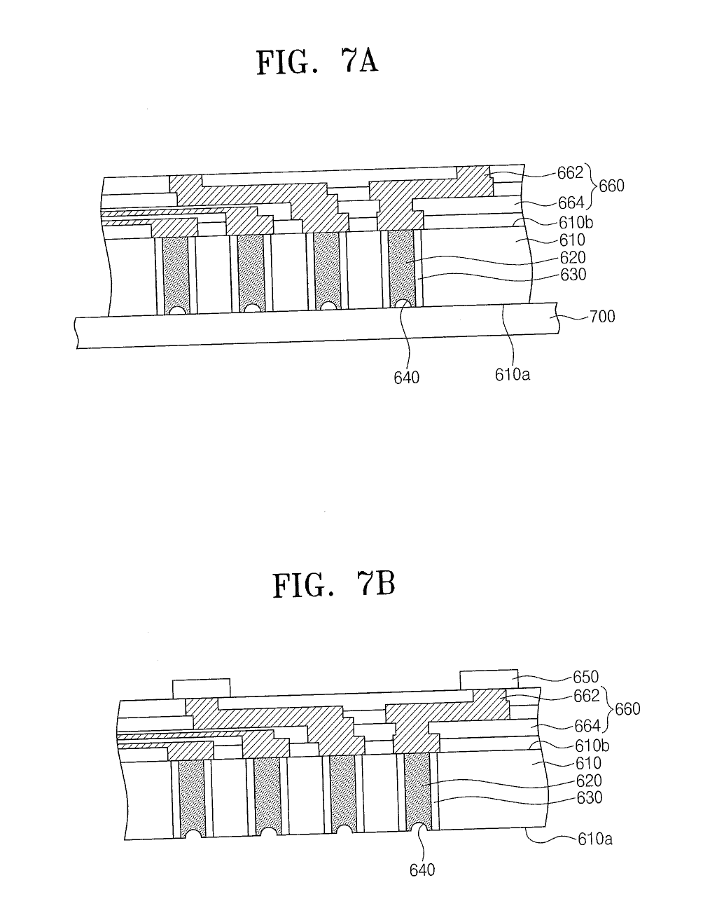

FIGS. 7A and 7B are cross-sectional views illustrating a method of manufacturing the probing interposer 601 of FIG. 6 according to some example embodiments of the present inventive concepts. FIGS. 7A and 7B illustrate an example of a subsequent process, which may be performed after the process described with reference to FIGS. 5A through 5H.

Referring to FIG. 7A, a polishing process may be performed on the second surface 610b of the supporting substrate 610 to expose the at least one via pattern 620, and the re-distribution layer 660 may be formed on the second surface 610b of the supporting substrate 610. The re-distribution layer 660 may include the metal layers 662, which are electrically connected to the via patterns 620, and the insulating layer 664 which is provided between the metal layers 662.

Referring to FIG. 7B, the at least one electrode pad 650 may be formed on the re-distribution layer 660. The at least one electrode pad 650 may be in contact with the metal layers 662 of the re-distribution layer 660. The at least one electrode pad 650 may cover the metal layer 662 and a portion of the insulating layer 644. In some embodiments, a plurality of electrode pads 650 may be provided to be spaced apart from each other by, for example, a uniform distance. The at least one electrode pad 650 may be formed of, for example, a conductive material and may be electrically connected to the at least one via pattern 620 and the metal layers 662.

According to some example embodiments of the present inventive concepts, a probing interposer may be provided to have a via pattern, in which a concave portion is formed. The concave portion is configured to prevent a bump of a target device from being damaged, when the probing interposer is in contact with the target device.

According to some example embodiments of the present inventive concepts, a via pattern may be formed to penetrate the supporting substrate. The via pattern may serve as a current path passing through the supporting substrate. The via pattern may be provided to have a concave portion, allowing for the via pattern to be in contact with a bump of the target device without an additional metal layer, resulting in a simplified process of manufacturing the probing interposer.

While example embodiments of the inventive concepts have been particularly shown and described, it will be understood by one of ordinary skill in the art that variations in form and detail may be made therein without departing from the spirit and scope of the attached claims.

What is claimed is:

1. A probing interposer, comprising:
a supporting substrate with first and second surfaces facing each other; and
a plurality of via patterns penetrating the supporting substrate,
wherein each of the plurality of via patterns has a concave portion that is exposed through the first surface of the supporting substrate and has a shape recessed in a direction from the first surface of the supporting substrate toward the second surface of the supporting substrate, and
wherein the concave portion has a width that is smaller than that of the corresponding via pattern, and the width decreases in the direction from the first surface of the supporting substrate toward the second surface of the supporting substrate.

2. The probing interposer of claim 1, further comprising a plurality of electrode pads that are provided on the second surface of the supporting substrate and are electrically connected to the plurality of via patterns, respectively.

3. The probing interposer of claim 1, further comprising a re-distribution layer that is provided on the second surface of the supporting substrate and is electrically connected to the via patterns.

4. The probing interposer of claim 3, further comprising a plurality of electrode pads provided on the re-distribution layer,
wherein the plurality of electrode pads are electrically connected to the plurality of via patterns through the re-distribution layer.

5. The probing interposer of claim 4, wherein a first space between the plurality of electrode pads is larger than a second space between the plurality of via patterns.

6. The probing interposer of claim 5, wherein each of the plurality of electrode pads has a width larger than the second space between the plurality of via patterns.

7. The probing interposer of claim 1, wherein the plurality of via patterns are spaced apart from each other by a uniform distance, and
the first surface of the supporting substrate has an uneven surface, on which the concave portions are successively arranged.

8. The probing interposer of claim 1, wherein the concave portion has a surface shaped like a curved bowl.

9. The probing interposer of claim 1, wherein the plurality of via patterns comprise at least one of tungsten (W), lead (Pd), cobalt (Co), nickel (Ni), gold (Au), rhenium (Re), rhodium (Rh), or alloys thereof.

10. The probing interposer of claim 1, further comprising an insulating layer provided between the via patterns and the supporting substrate.

11. A test system, comprising:
a chuck configured to load a target device with a plurality of bumps;
a probing interposer configured to be in contact with the plurality of bumps of the target device; and
a probe card provided on the probing interposer, the probe card comprising probe tips configured to be in contact with the probing interposer and to apply test signals to the target device,
wherein the probing interposer comprises:
a supporting substrate with first and second surfaces facing each other; and
a plurality of via patterns provided to penetrate the supporting substrate,
wherein each of the plurality of via patterns has a concave portion that is recessed in a direction from the first surface of the supporting substrate toward the second surface of the supporting substrate,
the concave portions being used for contact between the plurality of via patterns and the plurality of bumps, and
the concave portion having a diameter smaller than that of the corresponding via pattern and being tapered in the direction from the first surface of the supporting substrate toward the second surface of the supporting substrate.

12. The test system of claim 11, wherein the probing interposer further comprises a plurality of electrode pads that are provided on the second surface of the supporting substrate and are in contact with the probe tips.

13. The test system of claim 11, wherein the probing interposer further comprises a re-distribution layer provided on the second surface of the supporting substrate,
wherein the re-distribution layer comprises:
a plurality of metal layers electrically connected to the plurality of via patterns; and
an insulating layer provided between the metal layers.

14. The test system of claim 13, wherein the probing interposer further comprises a plurality of electrode pads that are provided on the re-distribution layer and are in contact with the probe tips,
wherein a first space between the plurality of electrode pads is greater than a second space between the plurality of via patterns.

15. The test system of claim 11, wherein the concave portion has a recess depth smaller than a height of the bump protruding from the target device, when measured in the direction from the first surface toward the second surface.

16. A probing interposer, comprising:
a supporting substrate having a first surface and a second surface opposite the first surface; and
a plurality of via patterns extending through the supporting substrate from the first surface of the supporting substrate to the second surface of the supporting substrate in a vertical direction of extension relative to a horizontal direction of extension of the supporting substrate; and
a concave portion in each of the plurality of via patterns along the first surface of the support substrate, the concave portion being a recess extending from the first surface of the supporting substrate to the second surface of the supporting substrate.

17. The probing interposer of claim 16, further comprising an insulating layer provided between the via patterns and the supporting substrate extending through the supporting substrate from the first surface of the supporting substrate to the second surface of the supporting substrate in a vertical direction of extension relative to a horizontal direction of extension of the supporting substrate.

18. The probing interposer of claim 16, further comprising a plurality of electrode pads that are provided on the second surface of the supporting substrate and are electrically connected to the plurality of via patterns, respectively.

19. The probing interposer of claim 18, wherein the plurality of electrode pads cover an exposed surface of the plurality of via patterns, respectively.

20. The probing interposer of claim 16, wherein the concave portion has a width that is smaller than that of the corresponding via pattern, and the width decreases in the direction from the first surface of the supporting substrate toward the second surface of the supporting substrate.
